(19) United States
(12) Patent Application Publication
(10) Pub. No.: US 2017/0025486 A1
(43) Pub. Date: Jan. 26, 2017

(54) FLEXIBLE ORGANIC LIGHT-EMITTING DISPLAY DEVICE

(71) Applicant: Samsung Display Co., Ltd., Yongin-si (KR)

(72) Inventor: Ohjune Kwon, Yongin-si (KR)

(21) Appl. No.: 15/014,931

(22) Filed: Feb. 3, 2016

(30) Foreign Application Priority Data
Jul. 22, 2015 (KR) 10-2015-0103879

(51) Int. Cl. H01L 27/32; H01L 51/00; H01L 51/52

(52) U.S. Cl. CPC H01L 27/3246; H01L 51/5253; H01L 51/004; H01L 51/0038; H01L 2251/303; H01L 2251/301; H01L 2251/5338

(57) ABSTRACT

An organic light-emitting display device includes: a display substrate; an organic light-emitting device including a first electrode, an intermediate layer including an organic emission layer, and a second electrode; a pixel-defining layer; an anchor on the pixel-defining layer, the anchor having a cross-sectional width that narrows along a direction perpendicular to a surface of the display substrate; and a thin film encapsulation layer covering the organic light-emitting device and an outer surface of the anchor, the thin film encapsulation layer including an inorganic layer and an organic layer covering the inorganic layer.

### CROSS-REFERENCE TO RELATED APPLICATION

This application claims priority to and the benefit of Korean Patent Application No: 10-2015-0103879, filed on Jul. 22, 2015 in the Korean Intellectual Property Office, the disclosure of which is incorporated herein in its entirety by reference.

### BACKGROUND

1. Field

One or more exemplary embodiments of the present invention relate to an organic light-emitting display device.

2. Description of the Related Art

Generally, an organic light-emitting display device having a thin film transistor (TFT) may be used in mobile devices, such as smartphones, laptop computers, digital cameras, camcorders, personal digital assistants (PDA), notebook computers, and tablet personal computers (PC), or electronic devices, such as desktop computers, televisions, outdoor billboards, and a display device for exhibition.

Recently, slimmer display devices have been introduced into the market. Among them, flexible display devices that are easy to carry and applicable to various shapes of devices are in the spotlight as next generation display devices. Among them, a flexible display device based on organic light-emitting display technology is a strong candidate for flexible display devices.

### SUMMARY

One or more exemplary embodiments of the present invention include an organic light-emitting display device.

Additional aspects will be set forth, in part, in the description which follows and, in part, will be apparent from the description or may be learned by practice of the presented embodiments.

According to one or more exemplary embodiments of the present invention, an organic light-emitting display device includes: a display substrate having a plurality of sub-pixels thereon; an organic light-emitting device including a first electrode in each of the sub-pixels; an intermediate layer including an organic emission layer on each of the first electrodes; and a second electrode on each of the intermediate layers; a pixel-defining layer having a plurality of openings therein, ones of the openings exposing a portion of a respective one of the first electrodes; an anchor on the pixel-defining layer, the anchoring having a cross-sectional width that narrows along a direction perpendicular to a surface of the display substrate; and a thin film encapsulation layer covering the organic light-emitting device and an outer surface of the anchor, and includes an inorganic layer and an organic layer covering the inorganic layer.

The cross-sectional width of the anchor may narrow in a direction toward the surface of the display substrate.

The anchor may include: an upper surface spaced from a top surface of the pixel-defining layer; a lower surface contacting the top surface of the pixel-defining layer; and a lateral surface extending between the upper surface and the lower surface.

The upper surface of the anchor may have a greater surface area than the lower surface of the anchor.

An angle between the lateral surface of the anchor and the top surface of the pixel-defining layer may be an acute angle.

A portion of the inorganic layer of the thin film encapsulation layer may cover both the upper surface and the lateral surface of the anchor, and the organic layer of the thin film encapsulation layer may cover the portion of the inorganic layer.

A thickness of the portion of the inorganic layer on the upper surface of the anchor may be greater than a thickness of the portion of the inorganic layer on the lateral surface of the anchor.

A thickness of the inorganic layer on the lateral surface of the anchor may decrease from the upper surface of the anchor toward the lower surface of the anchor.

An angle between the portion of the inorganic layer on the lateral surface of the anchor and the top surface of the pixel-defining layer may be smaller than an angle between the lateral surface of the anchor and the top surface of the pixel-defining layer.

The organic layer may be thicker than the inorganic layer.

An interval of the pixel-defining layer adjacent the lower surface of the anchor and below the upper surface of the anchor extends around a perpihery of the anchor.

The intermediate layer may not be formed at the interval of the pixel-defining layer.

The inorganic layer of the thin film encapsulation layer may directly contact the pixel-defining layer at the interval of the pixel-defining layer.

The inorganic layer of the thin film encapsulation layer may extend over the intermediate layer, the interval of the pixel-defining layer, and the anchor.

The anchor may be at an edge of at least one of the sub-pixels.

The inorganic layer and the organic layer may be alternately stacked along a direction away from the display substrate.

The inorganic layer may include aluminum oxide, silicon oxynitride, silicon oxide, silicon nitride, silicon carbide, silicon titanium oxide, zirconium oxide, or zinc oxide.

The organic layer may include epoxy, polyimide, polyethylene terephthalate, polycarbonate, polyethylene, or polyacrylate.

The intermediate layer may further include a hole injection layer, a hole transport layer, an electron transport layer, or an electron injection layer.

The display substrate may include a flexible substrate.

### BRIEF DESCRIPTION OF THE DRAWINGS

These and/or other aspects will become apparent and more readily appreciated from the following description of exemplary embodiments, taken in conjunction with the accompanying drawings in which:

FIG. 1 is a perspective view illustrating an organic light-emitting display device in an unfolded state according to an exemplary embodiment;

FIG. 2 is a perspective view illustrating the organic light-emitting display device illustrated in FIG. 1 in a folded state;

FIG. 3 is a cross-sectional view illustrating a portion of one sub-pixel of an organic light-emitting display device according to an exemplary embodiment;

FIG. 4 is an enlarged cross-sectional view illustrating a thin film encapsulation layer stacked on a display substrate illustrated in FIG. 3; and

FIG. 5 is an enlarged cross-sectional view illustrating the region A of FIG. 4.

### DETAILED DESCRIPTION

As the inventive concept allows for various changes and numerous embodiments, exemplary embodiments will be illustrated in the drawings and described in detail in the written description. However, the presented exemplary embodiments are not intended to limit the inventive concept to particular modes of practice, and it is to be appreciated that all changes, equivalents, and substitutes that do not depart from the spirit and technical scope of the inventive concept are encompassed by the inventive concept. In the description of the inventive concept, certain detailed explanations of the related art may be omitted when it is deemed that they may unnecessarily obscure the essence of the inventive concept.

While terms, such as “first,” “second,” etc., may be used to describe various components, such components are not to be limited to the above terms. The above terms are used only to distinguish one component from another.

The terms used in the present specification are merely used to describe exemplary embodiments and are not intended to limit the inventive concept. An expression used in the singular encompasses the expression of the plural, unless it has a clearly different meaning in the context. In the present specification, it is to be understood that terms, such as “including,” “having,” and “comprising,” are intended to indicate the existence of the stated features, numbers, steps, actions, components, parts, or combinations thereof disclosed in the specification but are not intended to preclude the possibility that one or more other features, numbers, steps, actions, components, parts, or combinations thereof may exist or may be added.

It will be understood that when an element or layer is referred to as being “on,” “connected to,” or “coupled to” another element or layer, it may be directly on, connected, or coupled to the other element or layer or one or more intervening elements or layers may also be present. When an element is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements. As used herein, the term “and/or” includes any and all combinations of one or more of the associated listed items. Further, the use of “may” when describing embodiments of the present invention relates to “one or more embodiments of the present invention.” Expressions, such as “at least one of,” when preceding a list of elements, modify the entire list of elements and do not modify the individual elements of the list. Also, the term “exemplary” is intended to refer to an example or illustration. Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Hereinafter, an exemplary embodiment of an organic light-emitting display device is described below with reference to the accompanying drawings. In describing an exemplary embodiment with reference to the accompanying drawings, like reference numerals are given to like or corresponding components and repeated descriptions thereof may be omitted. Furthermore, in the figures, dimensions of the various elements, layers, etc. may be exaggerated for clarity of illustration.

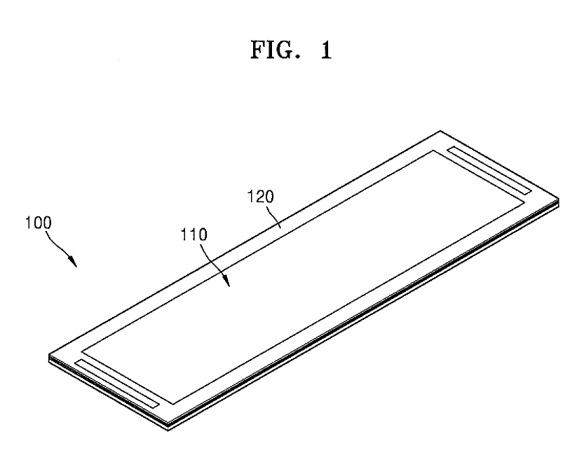

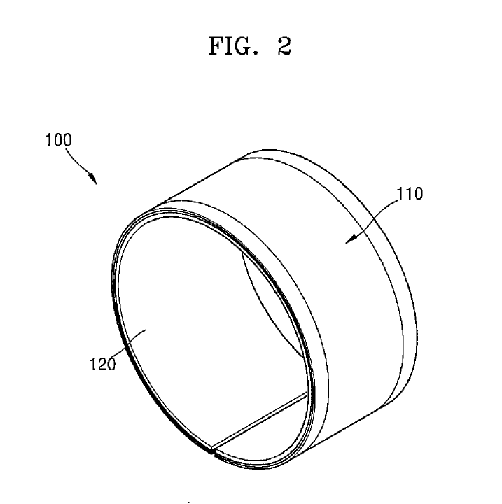

FIG. 1 is a perspective view illustrating an organic light-emitting display device 100 in an unfolded state according to an exemplary embodiment, and FIG. 2 is a perspective view illustrating the organic light-emitting display device 100 illustrated in FIG. 1 in a folded state.

Referring to FIGS. 1 and 2, the organic light-emitting display device 100 includes a flexible display panel 110 for displaying an image and a flexible casing 120 (e.g., a flexible housing) for supporting the flexible display panel 110. The flexible display panel 110 includes various flexible films, such as a display substrate, a touchscreen, and/or a polarization plate.

Though the organic light-emitting display device 100 is described as a flexible display device based on a flexible film as an example, the organic light-emitting display device 100 may be a rigid display device based on (e.g., formed on) glass.

A user may view an image under various states in which the organic light-emitting display device 100 is unfolded, curved, or cylindrically folded.

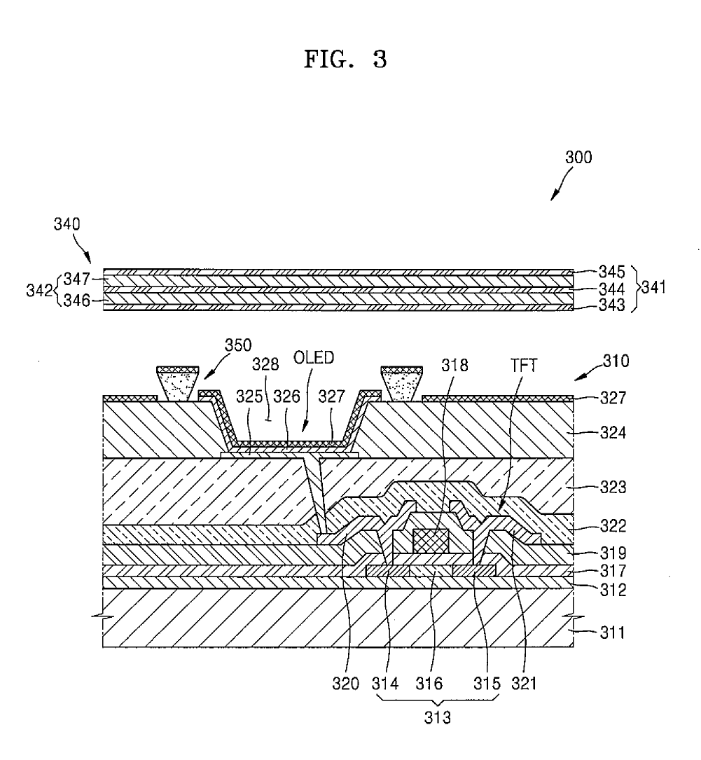

FIG. 3 is a cross-sectional view illustrating one sub-pixel of an organic light-emitting display device 300 according to an exemplary embodiment.

According to an exemplary embodiment, one sub-pixel includes a thin film transistor (TFT) and an organic light-emitting device (OLED). The TFT is not limited to the structure illustrated in FIG. 3, and the number of TFTs and the structure of the TFT may be variously modified.

Referring to the FIG. 3, the organic light-emitting display device 300 includes a flexible panel 310 and a thin film encapsulation (TFE) layer 340 on the flexible panel 310. The flexible panel 310 includes a display substrate 311, a TFT, an OLED, and a plurality of insulating layers.

The display substrate 311 may include a flexible insulating material. According to exemplary embodiments, the display substrate 311 may include a polymer material, such as polyimide (PO, polycarbonate (PC), polyethersulfone (PES), polyethylene terephthalate (PET), polyethylene naphthalate (PEN), polyacrylate (PAR), or fiber glass reinforced plastic (FRP). In another embodiment, the display substrate 311 may include (e.g., may be formed of) glass having a thickness that allows bending thereof.

The display substrate 311 may be transparent, semitransparent, or opaque.

A barrier layer 312 may be formed on the display substrate 311. The barrier layer 312 may cover the entire top surface (e.g., upper surface) of the display substrate 311. The barrier layer 312 may include an inorganic material and/or an organic material. The barrier layer 312 may include a single layer or multiple layers. The barrier layer 312 prevents penetration of impurities through the display substrate 311 into the TFT or the OLED and planarizes the top surface of the display substrate 311.

The TFT may be formed on the barrier layer 312. Though the TFT is described as a top gate transistor as an example according to an exemplary embodiment, a TFT having a different structure, such as a bottom gate transistor, may be provided.

A semiconductor active layer 313 may be disposed on the barrier layer 312.

The semiconductor active layer 313 includes a source region 314 and a drain region 315 doped with N-type impurity ions or P-type impurity ions. A region between the source region 314 and the drain region 315 may be a channel region 316 that is not doped with impurities. The semiconductor active layer 313 may include an organic semiconductor, an inorganic semiconductor, or amorphous silicon. According to an exemplary embodiment, the semiconductor active layer 313 may include an oxide semiconductor.

A gate insulating layer 317 may be deposited on the semiconductor active layer 313. The gate insulating layer 317 may include an inorganic layer. The gate insulating layer 317 may include a single layer or multiple layers.

A gate electrode 318 may be disposed on the gate insulating layer 317. The gate electrode 318 may include a metallic material having excellent conductivity. The gate electrode 318 may include a single layer or multiple layers.

An interlayer insulating layer 319 may be disposed on the gate electrode 318. The interlayer insulating layer 319 may include an inorganic layer and/or an organic layer.

A source electrode 320 and a drain electrode 321 may be disposed on the interlayer insulating layer 319. In one embodiment, contact openings (e.g., contact holes) are formed in the gate insulating layer 317 and the interlayer insulating layer 319 by removing a portion of the gate insulating layer 317 and the interlayer insulating layer 319. The source electrode 320 may be electrically connected to the source region 314 and the drain electrode 321 may be electrically connected to the drain region 315 via respective ones of the contact openings.

A passivation layer 322 may be disposed on the source electrode 320 and the drain electrode 321. The passivation layer 322 may include an inorganic layer and/or an organic layer. A planarization layer 323 may be disposed on the passivation layer 322. The planarization layer 323 may include an organic layer. In some embodiments, the passivation layer 322 and/or the planarization layer 323 may be omitted.

The TFT may be electrically connected to the OLED.

The OLED may be disposed on the planarization layer 323. The OLED may include a first electrode 325, an intermediate layer 326, and a second electrode 327.

The first electrode 325 corresponds to a pixel electrode and acts as an anode. The first electrode 325 may include various conductive materials. The first electrode 325 includes (e.g., may be) a transparent electrode or a reflective electrode. For example, when the first electrode 325 is a transparent electrode, the first electrode 325 includes a transparent conductive layer. When the first electrode 325 is a reflective electrode, the first electrode 325 includes a reflective layer and a transparent conductive layer on the reflective layer.

A pixel-defining layer 324 covers a top surface of the planarization layer 323 and a portion of the first electrode 325. The pixel-defining layer 324 may have an opening 328 that exposes a portion of the first electrode 325. The pixel-defining layer 324 limits an emission region of each sub-pixel by surrounding an edge (e.g., a peripheral edge) of the first electrode 325. The first electrode 325 may be patterned in every sub-pixel. The pixel-defining layer 324 may include an organic layer and/or an inorganic layer. The pixel-defining layer 324 may include a single layer or multiple layers.

The intermediate layer 326 may be disposed on the portion of the first electrode 325 that is exposed by the opening 328. The intermediate layer 326 may be formed by a deposition process.

According to an exemplary embodiment, the intermediate layer 326 includes an organic emission layer. According to other exemplary embodiments, the intermediate layer 326 includes an organic emission layer and further includes a hole injection layer (HIL), a hole transport layer (HTL), an electron transport layer (ETL), and/or an electron injection layer (EIL). According to yet another exemplary embodiment, the intermediate layer 326 is not limited to the above-described structure and includes the organic emission layer and may further include other various functional layers.

The second electrode 327 may be disposed on the intermediate layer 326.

The second electrode 327 corresponds to a common electrode and may act as a cathode. The second electrode 327 includes (e.g., may be) a transparent electrode or a reflective electrode. For example, when the second electrode 327 is a transparent electrode, the second electrode 327 includes a metallic layer (e.g., a thin metallic layer) and a transparent conductive layer on the metallic layer. When the second electrode 327 is a reflective electrode, the second electrode 327 includes a metallic layer.

According to an exemplary embodiment, a plurality of sub-pixels may be formed on the display substrate 311, and each sub-pixel may produce a red color, a green color, a blue color, or a white color. However, the present invention is not limited thereto.

The thin film encapsulation layer 340 may be formed to protect the OLED from external moisture, oxygen, etc. The thin film encapsulation layer 340 may include an inorganic layer 341 and an organic layer 342 alternately stacked on each other (e.g., stacked in turns). According to an exemplary embodiment, the inorganic layer 341 includes a first inorganic layer 343, a second inorganic layer 344, and a third inorganic layer 345. The organic layer 342 includes a first organic layer 346 and a second organic layer 347.

An anchor 350 may be formed on (e.g., installed on) the display substrate 311. The anchor 350 may solidify coupling between the display substrate 311 and the thin film encapsulation layer 340 (e.g., the anchor 350 may adhere the display substrate 311 and the thin film encapsulation layer 340 to each other). The width of the cross-section of the anchor 350 (e.g., a periphery of a cross-section of the anchor 350) may reduce or become smaller in a direction perpendicular to the display substrate 311 (e.g., in a direction perpendicular to a surface of the display substrate 311). The thin film encapsulation layer 340 may cover the anchor 350.

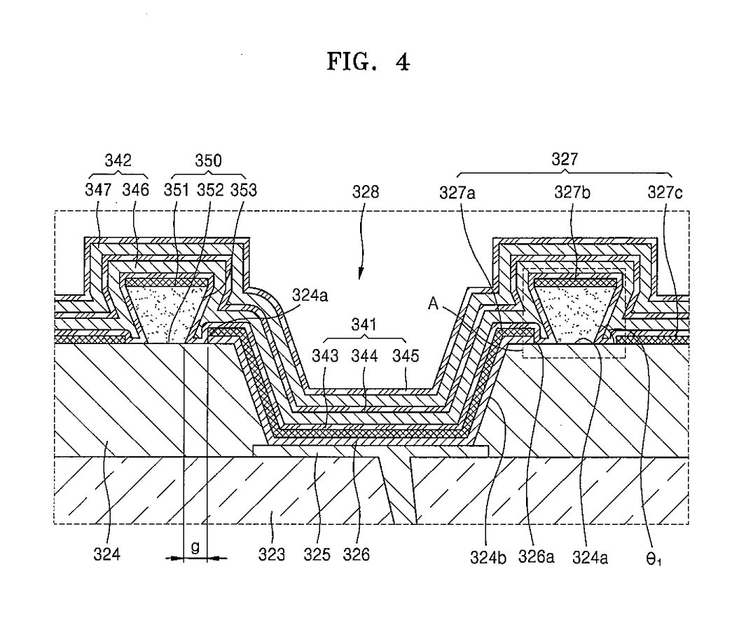

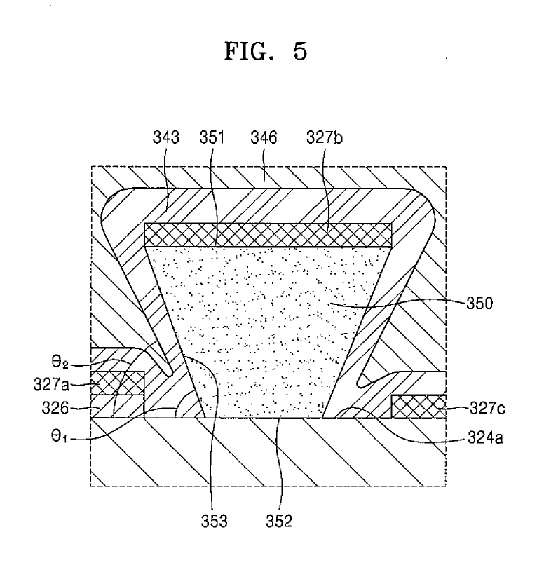

FIG. 4 is an enlarged cross-sectional view illustrating the thin film encapsulation layer 340 stacked on the display substrate 311 illustrated in FIG. 3, and FIG. 5 is an enlarged cross-sectional view illustrating the region A of FIG. 4.

Referring to FIGS. 4 and 5, the pixel-defining layer 324 may cover the edge of the first electrode 325. The opening 328 may expose the other portions of the first electrode 325 (e.g., the portions of the first electrode 325 other than the edge thereof) to the outside.

The intermediate layer 326 may be disposed on the exposed portion of the first electrode 325. According to an exemplary embodiment, the intermediate layer 326 includes an organic emission layer. The second electrode 327 may be stacked on the intermediate layer 326. When the second electrode 327 is a common electrode, the second electrode 327 may be formed over the entire region of the display substrate 311 (e.g., over the entire display substrate 311 or the entire display region of the display substrate 311).

At least one anchor 350 may be disposed adjacent an edge of (e.g., along a periphery or circumference of) the sub-pixel. For example, multiple anchors 350 may be formed between adjacent sub-pixels, or the anchors 350 may be formed at a corner of each sub-pixel; however, the present invention is not limited thereto.

The anchor 350 may be formed on a top surface 324a of the pixel-defining layer 324. The anchor 350 may be formed by using a negative photo resistor. According to an exemplary embodiment, the anchor 350 may include an insulating material (e.g., may include any material as far as it is an insulating material). The height of the anchor 350 may be about 3 micrometers.

The width of the cross-section of the anchor 350 may reduce or become smaller in a direction toward the display substrate 311 (see FIG. 3). For example, the anchor 350 may include an upper surface 351 away from (e.g., spaced from) the top surface 324a of the pixel-defining layer 324, a bottom surface 352 that contacts the top surface 324a of the pixel-defining layer 324, and a lateral surface 353 that connects the upper surface 351 with the bottom surface 352. The lateral surface 353 may connect the upper surface 351 with the bottom surface 352 along an oblique line (e.g., in a cross-sectional view, the lateral surface 353 may be an oblique line).

The anchor 350 may have a reverse tapered shape. According to an exemplary embodiment, the anchor 350 may have any structure in which the width (or the surface area) of the upper surface 351 of the anchor 350 is greater than the width (or the surface area) of the bottom surface 352 of the anchor 350. An angle θ₁ formed by the top surface 324a of the pixel-defining layer 324 and the lateral surface 353 of the anchor 350 may be an acute angle.

The thin film encapsulation layer 340 includes the inorganic layer 341 and the organic layer 342. The inorganic layer 341 and the organic layer 342 may be alternately stacked in a direction away from the display substrate 311. The inorganic layer 341 includes the first inorganic layer 343, the second inorganic layer 344, and the third inorganic layer 345. The organic layer 342 includes the first organic layer 346 and the second organic layer 347.

The inorganic layer 341 includes aluminum oxide (AlOₓ), silicon oxynitride (SiOₓN_{y}), silicon oxide (SiOₓ), silicon nitride (SiNₓ), silicon carbide (SiCₓ), silicon titanium oxide (SiTiOₓ), zirconium oxide (ZrOₓ), and/or zinc oxide (ZnO).

The organic layer includes epoxy, polyimide (PI), polyethylene terephthalate (PET), polycarbonate (PC), polyethylene (PE), and/or polyacrylate.

According to an exemplary embodiment, a capping layer for protecting the OLED may be further disposed on the second electrode 327. According to an exemplary embodiment, a halogenated metallic layer including lithium fluoride (LIF) may be further disposed between the OLED and the first inorganic layer 343.

The thin film encapsulation layer 340 covers the OLED and the anchor 350.

For example, the first inorganic layer 343 that is most adjacent to the OLED (e.g., that is nearest the OLED) may be directly stacked on (e.g., may directly contact) the OLED. The first inorganic layer 343 surrounds both the upper surface 351 and the lateral surface 353 of the anchor 350. The first organic layer 346 may cover a corresponding portion of the first inorganic layer 343. The second inorganic layer 344, the second organic layer 347, and the third inorganic layer 345 may be sequentially stacked on the first organic layer 346 in the direction away from the display substrate 311.

The thickness of a portion of the first inorganic layer 343 on the upper surface 351 of the anchor 350 may be greater than the thickness of a portion of the first inorganic layer 343 on the lateral surface 353 of the anchor 350.

For example, when the first inorganic layer 343 is deposited on the outer surface of the anchor 350 by using a chemical vapor deposition (CVD) method, a raw material of the first inorganic layer 343 may be less deposited (e.g., more sparsely deposited) at the lower end of the lateral surface of the anchor 350 than at the upper surface 351 of the anchor 350 due to the reverse taper-shaped anchor 350.

Because the raw material of the first inorganic layer 343 is not easily deposited on the lateral surface 353 of the anchor 350, the thickness of the first inorganic layer 343 may gradually thin toward the lower end of the lateral surface 353 of the anchor 350 from the upper surface 351 of the anchor 350.

According to an exemplary embodiment, an angle θ₂ formed by a portion of the first inorganic layer 343 on the lateral surface 353 of the anchor 350 and the top surface 324a of the pixel-defining layer 324 may be smaller than the angle θ₁ formed by the top surface 324a of the pixel-defining layer 324 and the lateral surface 353 of the anchor 350.

For example, compared to a case in which the first inorganic layer 343 is not disposed on the anchor 350, the angle formed by the anchor 350 at where the first inorganic layer 343 may have been deposited and the top surface 324a of the pixel-defining layer 324 may be even smaller than the angle θ₂. Therefore, a portion of the anchor 350 on which the first inorganic layer 343 is disposed has an incline due to the thickness of the deposited first inorganic layer 343. Therefore, when the first organic layer 346 is deposited on the first inorganic layer 343, coupling between the first organic layer 346 and the anchor 350 may be further reinforced.

The thickness of the first organic layer 346 may be greater than the thickness of the first inorganic layer 343. For example, the thickness of the first inorganic layer 343 may be about 1 micrometer and the thickness of the first organic layer 346 may be about 10 micrometers. When the first organic layer 346 is deposited on the first inorganic layer 343, the first organic layer 346 may planarize the surface of the first inorganic layer 343.

An area or interval “g”, where the top surface 324a of the pixel-defining layer 324 is exposed, may be formed along the periphery of the anchor 350. The interval “g” may correspond to a region in which the intermediate layer 326 is not formed. According to an exemplary embodiment, the interval “g” may correspond to a region in which the second electrode 327 is also not formed. Therefore, the pixel-defining layer 324 and the first inorganic layer 343 may directly contact each other at the interval “g” where the pixel-defining layer 324 is exposed.

For example, the anchor 350 may be formed on the top surface 324a of the pixel-defining layer 324. Then, the intermediate layer 326 and the second electrode 327 may be sequentially deposited on the display substrate 311.

The intermediate layer 326 includes an organic emission layer. The intermediate layer 326 may be disposed at a region corresponding to each sub-pixel. The intermediate layer 326 may pass by (e.g., may extend over) a lateral surface 324b of the pixel-defining layer 324 and extend up to a portion of the top surface 324a of the pixel-defining layer 324. The interval “g” may be a space between an edge 326a of the intermediate layer 326 and the anchor 350.

The second electrode 327 may be disposed over the entire region of the display substrate 311. The second electrode 327 may include a first portion 327a on the intermediate layer 326, a second portion 327b on the upper surface 351 of the anchor 350, and a third portion 327c between adjacent sub-pixels. The second electrode 327 may not be disposed on the lateral surface 353 of the anchor 350.

The first portion 327a and the third portion 327c of the second electrode 327 may be separated from the second portion 327b of the second electrode 327. For example, the first portion 327a and the third portion 327c may be separated from the second portion 327b on the upper surface 351 of the anchor 350 and may surround the periphery of the anchor 350 with the interval “g” disposed therebetween.

Because the anchor 350 has a reverse tapered shape, a raw material of the second electrode 327 is not easily deposited on the lateral surface 353 of the anchor 350. Therefore, the interval “g” may be formed at the periphery of the anchor 350.

According to an exemplary embodiment, the intermediate layer 326 may include the organic emission layer and may be disposed on the lateral surface 324b of the pixel-defining layer 324. The interval “g” may be formed at the top surface 324a of the pixel-defining layer 324.

According to an exemplary embodiment, the intermediate layer 326 may include the organic emission layer and may be disposed on the lateral surface 324b of the pixel-defining layer 324, the top surface 324a of the pixel-defining layer 324, and the upper surface 351 of the anchor 350. The interval “g” may be formed at a portion of the top surface 324a of the pixel-defining layer 324 that corresponds to a region at which the intermediate layer 326 is not formed.

According to an exemplary embodiment, the intermediate layer 326 may include a hole injection layer, a hole transport layer, an electron transport layer, and/or an electron injection layer in addition to the organic emission layer. Because the hole injection layer, the hole transport layer, the electron transport layer, and/or the electron injection layer may act as a common layer, these layers, like the second electrode 327, may be separated into a portion corresponding to the upper surface 351 of the anchor 350 and a portion corresponding to the other regions other than the upper surface 351 of the anchor 350.

As described above, because the interval “g” may be formed at a portion of the top surface 324a of the pixel-defining layer 324 that corresponds to a region at which the intermediate layer 326 is not formed, the pixel-defining layer 324 and the thin film encapsulation layer 340 may directly contact each other.

Furthermore, the first inorganic layer 343 of the thin film encapsulation layer 340 may extend over the upper portion of the intermediate layer 326, the interval “g”, and the outer surface of the anchor 350. The first organic layer 346 may be formed on a corresponding portion of the first inorganic layer 343.

As described above, in the organic light-emitting display device according to an exemplary embodiment, the anchor and the thin film encapsulation layer are solidly coupled to each other. Therefore, a coupling force between the display substrate and the thin film encapsulation layer of the organic light-emitting display device is improved.

While this disclosure has been particularly shown and described with reference to exemplary embodiments thereof, it will be understood by those skilled in the art that various changes in form and details may be made therein without departing from the spirit and scope of the disclosure as defined by the appended claims. Also, the embodiments disclosed herein should not be construed as limiting the technical spirit of the disclosure, but all technical spirits within the scope of the appended claims and their equivalents should be construed as being included in the disclosure.

What is claimed is:

1. An organic light-emitting display device comprising:
a display substrate having a plurality of sub-pixels thereon;
an organic light-emitting device comprising:
a first electrode in each of the sub-pixels;
an intermediate layer comprising an organic emission layer on each of the first electrodes; and
a second electrode on each of the intermediate layers;
a pixel-defining layer having a plurality of openings therein, ones of the openings exposing a portion of a respective one of the first electrodes;
an anchor on the pixel-defining layer, the anchor having a cross-sectional width that narrows along a direction perpendicular to a surface of the display substrate; and
a thin film encapsulation layer covering the organic light-emitting device and an outer surface of the anchor, the thin film encapsulation layer comprising an inorganic layer and an organic layer covering the inorganic layer.

2. The device of claim 1, wherein the cross-sectional width of the anchor narrows in a direction toward the surface of the display substrate.

3. The device of claim 2, wherein the anchor comprises:
an upper surface spaced from a top surface of the pixel-defining layer;
a lower surface contacting the top surface of the pixel-defining layer; and
a lateral surface extending between the upper surface and the lower surface.

4. The device of claim 3, wherein the upper surface of the anchor has a greater surface area than the lower surface of the anchor.

5. The device of claim 3, wherein an angle between the lateral surface of the anchor and the top surface of the pixel-defining layer is an acute angle.

6. The device of claim 3, wherein a portion of the inorganic layer of the thin film encapsulation layer covers both the upper surface and the lateral surface of the anchor, and the organic layer of the thin film encapsulation layer covers the portion of the inorganic layer.

7. The device of claim 6, wherein a thickness of the portion of the inorganic layer on the upper surface of the anchor is greater than a thickness of the portion of the inorganic layer on the lateral surface of the anchor.

8. The device of claim 7, wherein a thickness of the inorganic layer on the lateral surface of the anchor decreases from the upper surface of the anchor toward the lower surface of the anchor.

9. The device of claim 8, wherein an angle between the portion of the inorganic layer on the lateral surface of the anchor and the top surface of the pixel-defining layer is smaller than an angle between the lateral surface of the anchor and the top surface of the pixel-defining layer.

10. The device of claim 6, wherein the organic layer is thicker than the inorganic layer.

11. The device of claim 6, wherein an interval of the pixel-defining layer adjacent the lower surface of the anchor and below the upper surface of the anchor extends around a periphery of the anchor.

12. The device of claim 11, wherein the intermediate layer is not formed at the interval of the pixel-defining layer.

13. The device of claim 12, wherein the inorganic layer of the thin film encapsulation layer directly contacts the pixel-defining layer at the interval of the pixel-defining layer.

14. The device of claim 11, wherein the inorganic layer of the thin film encapsulation layer extends over the intermediate layer, the interval of the pixel-defining layer, and the anchor.

15. The device of claim 1, wherein the anchor is at an edge of at least one of the sub-pixels.

16. The device of claim 1, wherein the inorganic layer and the organic layer are alternately stacked along a direction away from the display substrate.

17. The device of claim 16, wherein the inorganic layer comprises aluminum oxide, silicon oxynitride, silicon oxide, silicon nitride, silicon carbide, silicon titanium oxide, zirconium oxide, or zinc oxide.

18. The device of claim 16, wherein the organic layer comprises epoxy, polyimide, polyethylene terephthalate, polycarbonate, polyethylene, or polyacrylate.

19. The device of claim 1, wherein the intermediate layer further comprises a hole injection layer, a hole transport layer, an electron transport layer, or an electron injection layer.

20. The device of claim 1, wherein the display substrate comprises a flexible substrate.
